(19) United States
(12) Patent Application Publication
(10) Pub. No.: US 2009/0168336 A1
(43) Pub. Date: Jul. 2, 2009

(54) Support Device, Electronic Equipment System, and Electronic Equipment

(75) Inventors: Satoshi Yokote, Tokyo (JP); Koji Abe, Tokyo (JP); Tomomi Murayama, Tokyo (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/240,154

(22) Filed: Sep. 29, 2008

(30) Foreign Application Priority Data
Dec. 26, 2007 (JP) 2007-333967

(51) Int. Cl. H05K 7/14

(52) U.S. Cl. 361/679.55

(57) ABSTRACT

According to one embodiment, a support device includes: a casing having one end, the other end opposite to the one end, and a placement plane for mounting an electronic equipment having a certain width; an external connection terminal for connecting to the electronic equipment, the external connection terminal being provided on the placement plane at a position at a first distance from a center of the placement plane to the one end; and an engagement piece having a claw part and being provided on the placement plane at a position at a second distance from the center of the placement plane to the other end.

### CROSS-REFERENCE TO RELATED APPLICATIONS

This application is based upon and claims the benefit of priority from Japanese Patent Application No. 2007-333967, filed on Dec. 26, 2007, the entire contents of which are incorporated herein by reference.

### BACKGROUND

1. Field

This invention relates to a support device, an electronic equipment system, and an electronic equipment.

2. Description of the Related Art

A cradle used to supply power to an electronic equipment such as an electronic camera and to connect an electronic equipment and a personal computer, etc., for communications is known (see JP-A-2003-68394, for instance).

The cradle described in JP-A-2003-68394 includes a connector for connecting a socket part (also called a connector) provided in an electronic equipment thereto and an escape member for escaping with installation of the electronic equipment. According to the configuration, it is not until that the escape member escapes as an electronic machine is installed in the cradle that the connector is first exposed, consequently the connector can be prevented from being exposed to outside when the electronic equipment is not installed in the cradle.

However, in the cradle in the related art, the electronic equipment is held only by the connector and thus when the electronic equipment is detached from the cradle, the connector may receive an extra load to be broken.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of an electronic equipment system according to a first embodiment of the invention;

FIG. 2 is an exemplary perspective view of a portable computer configuring a part of the electronic equipment system;

FIG. 3 is an exemplary perspective view of a cradle configuring a part of the electronic equipment system;

FIG. 4 is an exemplary perspective view of a cradle viewed from the bottom thereof;

FIG. 5 is an exemplary perspective view of a subboard;

FIG. 6A is an exemplary exploded perspective view of the hook;

FIG. 6B is an exemplary sectional view of the hook to show an assembly state thereof;

FIG. 7 is an exemplary block diagram to show a system configuration of a portable computer;

FIGS. 8A to 8C show an exemplary attaching operation of the portable computer on the cradle;

FIGS. 9A to 9C show an exemplary detaching operation of the portable computer from the cradle; and

FIG. 10 is an exemplary perspective view of an electronic equipment system according to a second embodiment of the invention.

### DETAILED DESCRIPTION

Various embodiments according to the invention will be described hereinafter with reference to the accompanying drawings. In general, according to one embodiment of the invention, a support device includes: a casing having one end, the other end opposite to the one end, and a placement plane for mounting an electronic equipment having a certain width; an external connection terminal for connecting to the electronic equipment, the external connection terminal being provided on the placement plane at a position at a first distance from a center of the placement plane to the one end; and an engagement piece having a claw part and being provided on the placement plane at a position at a second distance from the center of the placement plane to the other end.

### First Embodiment

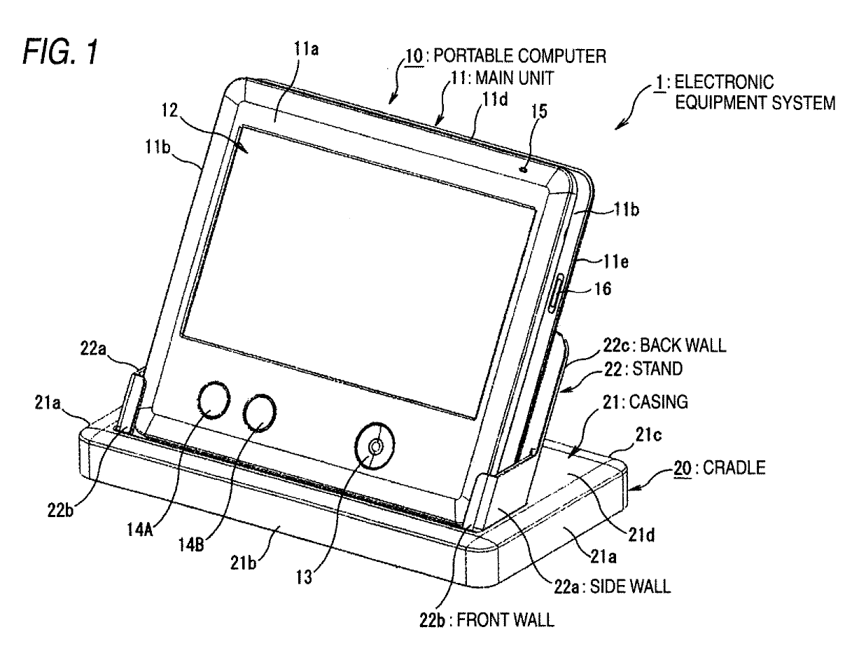

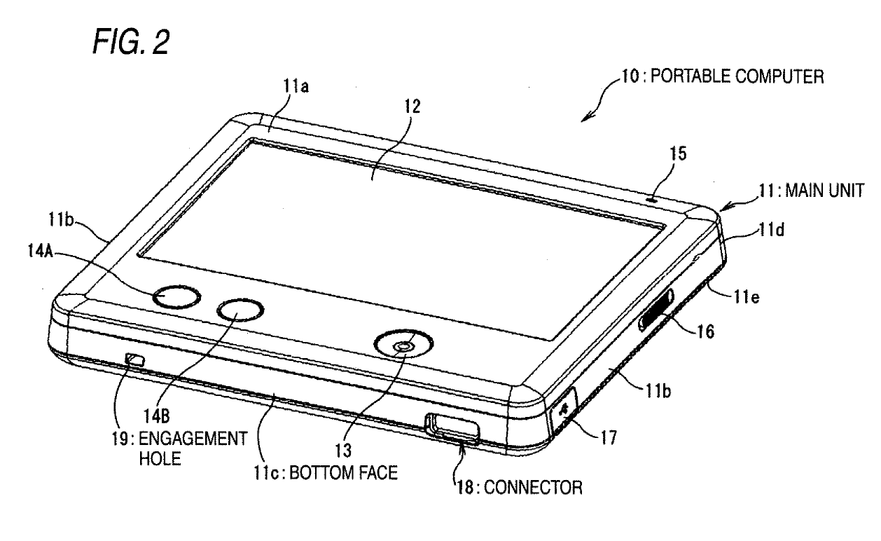

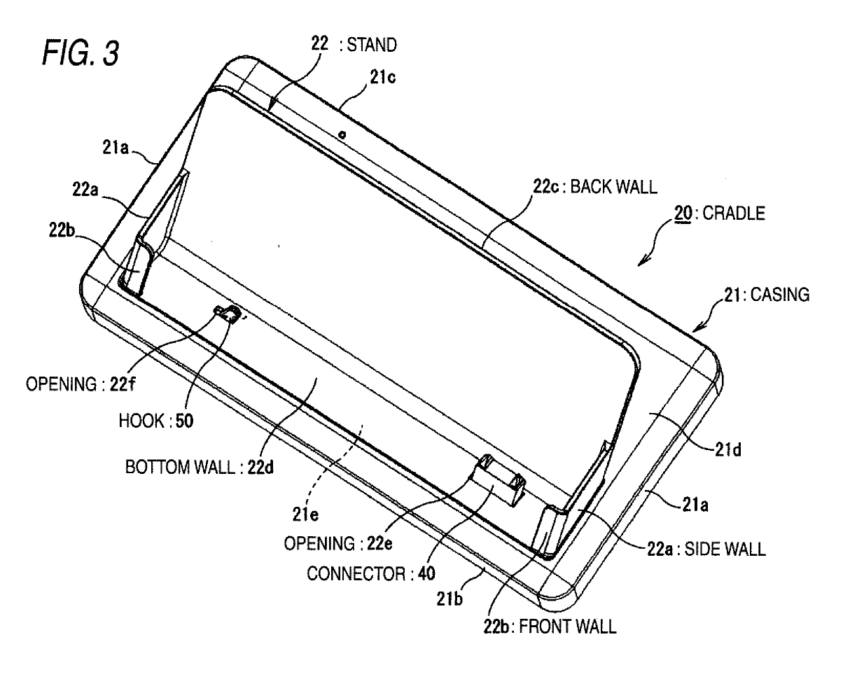

FIG. 1 is an exemplary perspective view of an electronic equipment system according to a first embodiment of the invention, FIG. 2 is an exemplary perspective view of a portable computer configuring a part of the electronic equipment system, and FIG. 3 is an exemplary perspective view of a cradle configuring a part of the electronic equipment system.

(Electronic Equipment System)

An electronic equipment system 1 is configured of a cradle (support device) 20 placed mainly on a desktop, etc., for use and a tablet portable computer (electronic equipment) 10 that can be attached to and detached from the cradle 20, as shown in FIG. 1.

(Portable Computer)

The portable computer (hereinafter, also called simply “computer”) 10 can be driven by a battery in a state in which it is removed from the cradle 20. The portable computer 10 includes a main unit (first casing) 11 shaped roughly like a rectangle having a front 11a, side faces 11b, a bottom face (first face) 11c, a top face lid, and a back lie, as shown in FIGS. 1 and 2.

A display section 12 configured of a Liquid Crystal Display (LCD) and a tablet (described later) stacked on each other is placed almost in the center of the front 11a of the main unit 11, a cursor key 13, a left click switch 14A, and a right click switch 14B are placed below the display section 12, and a microphone 15 is placed above the display section 12.

A power switch 16 and a Universal Serial Bus (USB) terminal 17 are placed on the right side face 11b of the main unit 11, and a connector (first external connection terminal) 18 and an engagement hole 19 are placed on the bottom face 11c of the main unit 11. The connector 18 is provided at a position at a first distance from the center of the bottom face 11c to the USB terminal 17 on the bottom face 11c. The engagement hole 19 is provided at a position at a second distance from the center of the bottom face 11c to the opposite direction to the USB terminal 17 on the bottom face 11c. A magnetic substance (not shown) that detects detachment of the computer 10 from the cradle 20 magnetically is placed inside the bottom face 11c.

The connector is connected to a connector (second external connection terminal) 40 shown in FIG. 3 provided on the cradle 20, and is provided at a position shifted to the right direction from the center of the bottom face 11c in FIG. 2 so as not to project from the bottom face 11c.

A hook (engagement piece) 50 shown in FIG. 3 provided on the cradle 20 is retained in the engagement hole 19 and the engagement hole 19 and is provided at a position shifted to the left direction from the center of the bottom face 11c in FIG. 2.

(Cradle)

The cradle 20 has a function of supplying power to the computer 10 and a function of providing the computer 10 with expandability by communicating with an external apparatus such as external storage. The cradle 20 is not limited to these functions; for example, it may be an electronic equipment such as a personal computer or external storage. The cradle 20 includes a casing (second casing) 21 incorporating various boards and a stand 22 fixed to the casing 21 for supporting the computer 10, as shown in FIGS. 1 and 3.

The casing 21 has side walls 21a, a front wall 21b, a back wall 21c, a top wall 21d, and a bottom wall 21e (described later). A bottom wall 22d of the stand 22 is provided on the bottom wall 21e. The connector 40 is attached to the bottom wall 21e of the casing 21. It is provided on the bottom wall 21e of the casing 21 and is placed at a position at a first distance from the center of the bottom wall 21e to one end (the right side wall 21a viewed from the front wall 21b in FIG. 3) on the bottom wall 21e.

The stand 22 has a pair of side walls 22a, front walls 22b, and a back wall 22c as a guide when the computer 10 is attached to the cradle 20, and the above-mentioned bottom wall 22d against which the bottom face 11c of the computer 10 abuts. The top face of the bottom wall 22d becomes a placement plane for attaching the computer 10. The stand 22 is fixed to the casing 21 by a screw, but may be configured integrally with the casing 21. The casing 21 may be provided with a depression for guiding the computer 10 without providing the stand 22, in which case the top face of the bottom wall 21e of the casing 21 becomes a placement plane for attaching the computer 10. The front walls 22b are provided only on both sides, but may be provided continuously so as to connect the left and right side walls 22a if the operability of the cursor key 13, the left click switch 14A, and the right click switch 14B are not impaired.

The side walls 22a and the front walls 22b are set to a height lower than the back wall 22c; the height is a height capable of regulating the position of the lower outer peripheral part of the computer 10 before the connector 18 provided on the computer 10 comes in contact with the connector 40 provided on the cradle 20.

The bottom wall 22d is provided with an opening 22e for inserting the connector 40 shown in FIG. 3 and an opening 22f for inserting the hook 50 shown in FIG. 3. The hook 50 is provided on the bottom wall 22d of the stand 22 and is placed at a position at a second distance from the center of the bottom wall 22d to the other end (the left side wall 21a viewed from the front wall 21b in FIG. 3) on the bottom wall 22d.

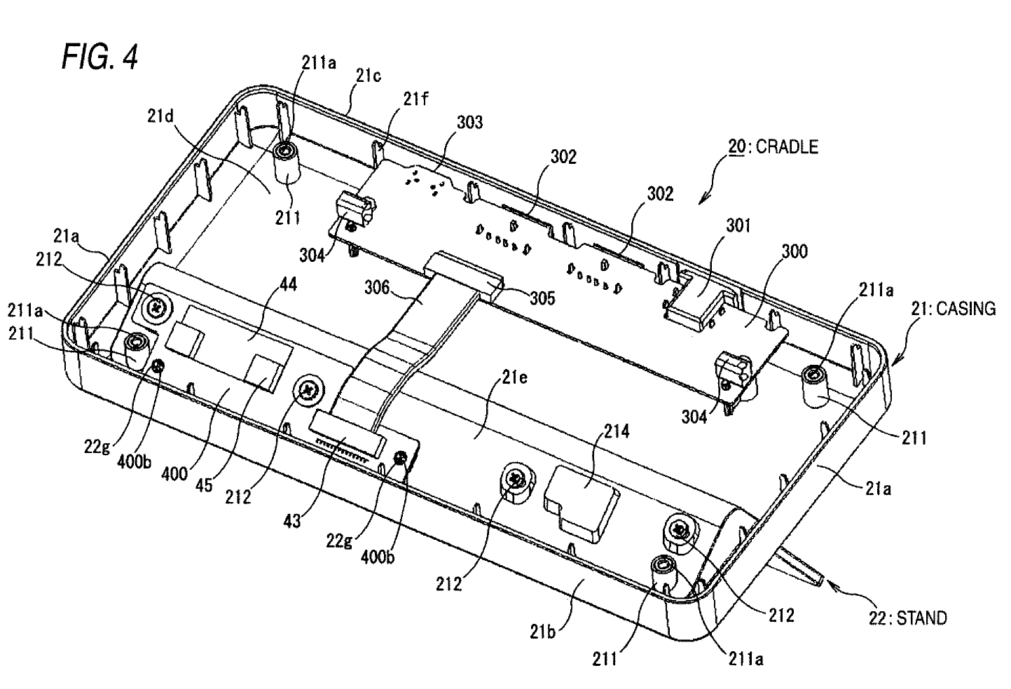

FIG. 4 is an exemplary perspective view of the cradle 20 viewed from the bottom thereof. A bottom plate for closing the bottom face of the casing 21 is removed in the figure. To reinforce the side walls 21a, the front wall 21b, and the back wall 21c, the casing 21 is formed with a reinforcing piece from the top wall 21d. Studs 211 each formed with a tapped hole 211a are projected on the top wall 21d and the bottom plate is fixed to the tapped holes 211a by screws.

A main board 300 is placed on the top wall 21d of the casing 21, and a subboard 400 is placed on a bottom wall 21e.

The bottom wall 21e is provided with a hook housing part 214 for housing the hook 50 having a shape bent like a saddle, a rectangular socket (not shown) into which a positioning projection 22g provided on the stand 22 fits, attachment holes (not shown) for attaching the subboard 400 and the stand 22, and studs 211 for fixing the bottom plate.

A power supply terminal part 301, USB terminals 302, and a mini USB terminal 303 are mounted on the main board 300 so that they are exposed to the back wall 21c of the casing 21, and a spacer 304 for securing a space from the bottom plate (not shown) and a connector 305 connecting to the subboard 400 are provided with the main board 300.

A plate 44, elastic bodies 45 of a sponge, rubber, etc., provided on the plate 44 for elastically pressing a bottom body (not shown), and a connector 43 for connecting the main board 300 are provided with the back of the subboard 400. The connector 43 on the subboard 400 is connected to the connector 305 on the main board 300 by a flexible wiring board 306.

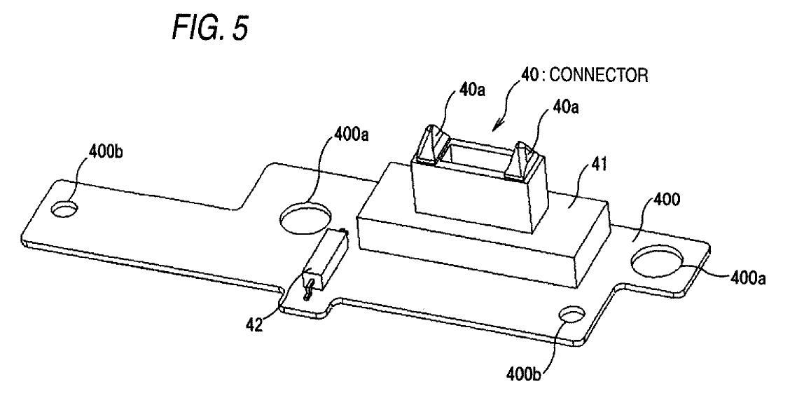

FIG. 5 is an exemplary perspective view of the subboard 400. The connector 40, a pedestal 41 to which the connector 40 is attached, and a magnetic sensor 42 are mounted on the subboard 400, and attachment holes 400a and positioning holes 400b are made in the subboard 400. The connector 40 is provided with a pair of pyramid-shaped guide parts 40a for guiding the connector 40 into the connection position of the mated connector 18. If a shift length of the connection position between the connector 40 and the mated connector 18 is within the range in which the connector can be guided according to the guide parts 40a, the subboard 400 can make a horizontal move for allowing the connector 40 to be connected to the mated connector 18. The guide parts may be provided on both the connectors 18 and 40 or may be provided only on the mated connector 18.

The magnetic sensor 42 magnetically detects detachment from of the computer 10 from the cradle 20 in response to the distance from the magnetic substance provided in the computer 10. The magnetic sensor 42 may be provided in the computer 10 and the magnetic substance may be provided in the cradle 20.

(Hook)

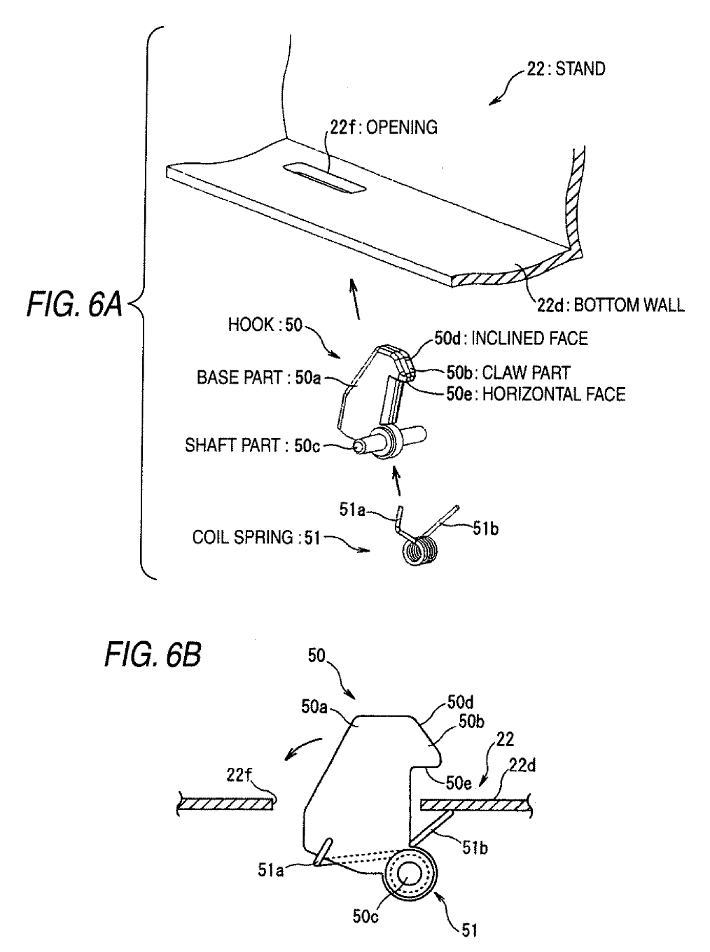

FIGS. 6A and 6B show a structure example of the hook; FIG. 6A is an exploded perspective view of the hook and FIG. 6B is a sectional view of the hook to show an assembly state thereof. The hook 50 is configured of a base part 50a, a claw part 50b provided above the base part 50a, and a shaft part 50c provided below the base part 50a, and is configured as a one-piece molding using a material of a resin, etc. The claw part 50b has an inclined face 50d and a horizontal face 50e.

The shaft part 50c is journaled by a bearing (not shown) provided on the lower face side of the bottom wall 22d of the stand 22, a coil spring 51 is attached to the shaft part 50c of the hook 50, one L-shaped end part 51a of the coil spring 51 is retained in the base part 50a of the hook 50, and a linear end part 51b of the coil spring 51 is abutted against the lower face of the bottom wall 22d of the stand 22 for assembly.

The coil spring 51 gives an elastic rotation force to the hook 50 to an opposite direction against the arrow direction shown in FIG. 6B. Accordingly, the claw part 50b of the hook 50 is elastically supported for rotation from a first state in which at least a part of the claw part 50b projects from the bottom wall 22d to a second state in which the claw part 50b projects to a perpendicular direction from the bottom wall 22d while applying a certain force between the first state and the second state with the claw part 50b remaining in the first state. A rotation force similar to that of the coil spring 51 may be given to the hook 50 by a tension spring or a compression spring.

(System Configuration of Portable Computer)

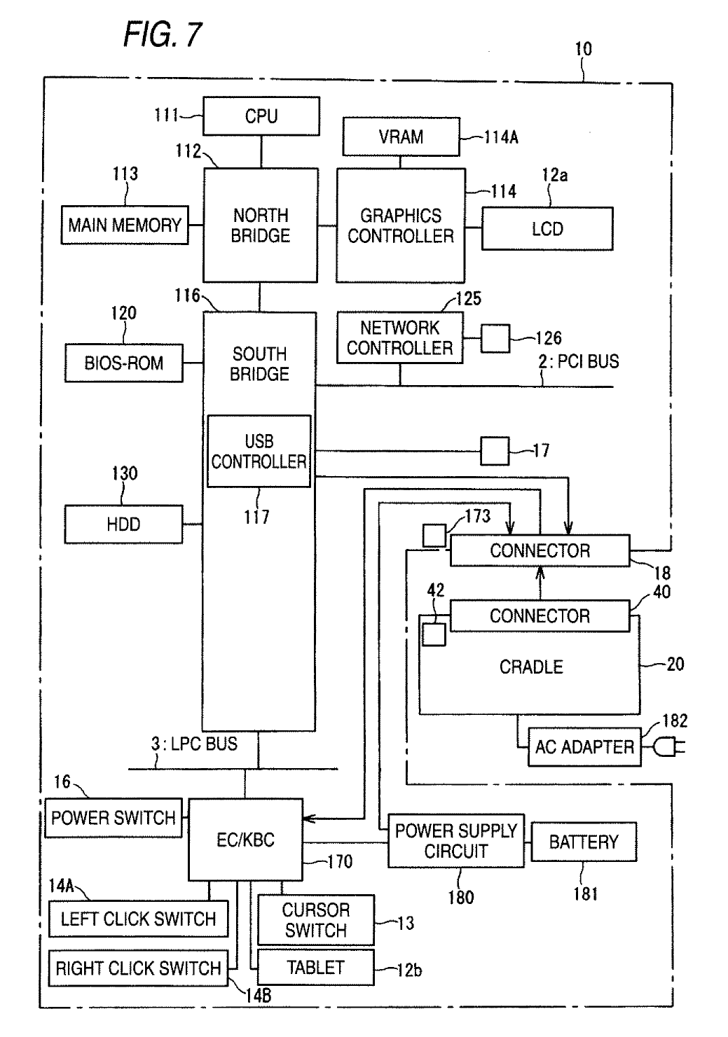

FIG. 7 is an exemplary block diagram to show the system configuration of the portable computer 10. The computer 10 includes a CPU 111, a north bridge 112, main memory 113, a graphics controller 114, an LCD 12a, a tablet 12b, a south bridge 116, BIOS-ROM 120, a network controller 125, a hard disk drive (HDD) 130, a connector is, an embedded controller/keyboard controller IC (EC/KBC) 170, a power supply circuit 180, and the like.

The CPU 111 is a processor provided for controlling the operation of the computer 10. It executes an operating system and various application programs loaded into the main memory 113 from the HDD 130. The CPU 111 also executes a system Basic Input Output System (BIOS) stored in the BIOS-ROM 120. The system BIOS is a program for hardware control.

The north bridge 112 is a bridge device for connecting a local bus of the CPU 111 and the south bridge 116. The north bridge 112 also has a function of executing communications with the graphics controller 114 through an Accelerated Graphics Port (AGP) bus, etc. Further, the north bridge 112 also contains a memory controller for controlling access to the main memory 113.

The graphics controller 114 is a display controller for controlling the LCD 12a used as a display monitor of the computer 10. The graphics controller 114 displays data written into video memory (VRAM) 114A by the operating system or the application program on the LCD 12a.

The south bridge 116 contains an Integrated Drive Electronics (IDE) controller for controlling the HDD 130 and a USB controller 117 for controlling the USB terminal 17. The south bridge 116 is connected to a Peripheral Component Interconnect (PCI) bus 2 and a Low Pin Count (LPC) bus 3.

The network controller 125 is connected to the PCI bus 2. It executes communications with an external network machine through a LAN cable connected to a LAN port 126.

The EC/KBC 170 is a one-chip microcomputer into which an embedded controller (EC) for power management and a keyboard controller (KBC) for controlling the tablet 12b, the cursor key 13, the left click switch 14A, the right click switch 14B, etc., are integrated. The EC/KBC 170 has a function of turning on/off the power of the computer 10 in cooperation with the power supply circuit 180 in response to user operation.

The power supply circuit 180 generates system power to be supplied to the components of the computer 10 using external power supplied through an AC adapter 182 or a chargeable battery 181.

The computer 10 is connected to the cradle 20 by the connector 18 as described above. Each of the connectors 18 and 40 are provided with about 50 pins, for example. Some of the pins are defined as power supply pins for supplying operation power from the cradle 20 to the computer 10 and some are defined as signal pins connected to the USB signal lines.

(Attaching Operation)

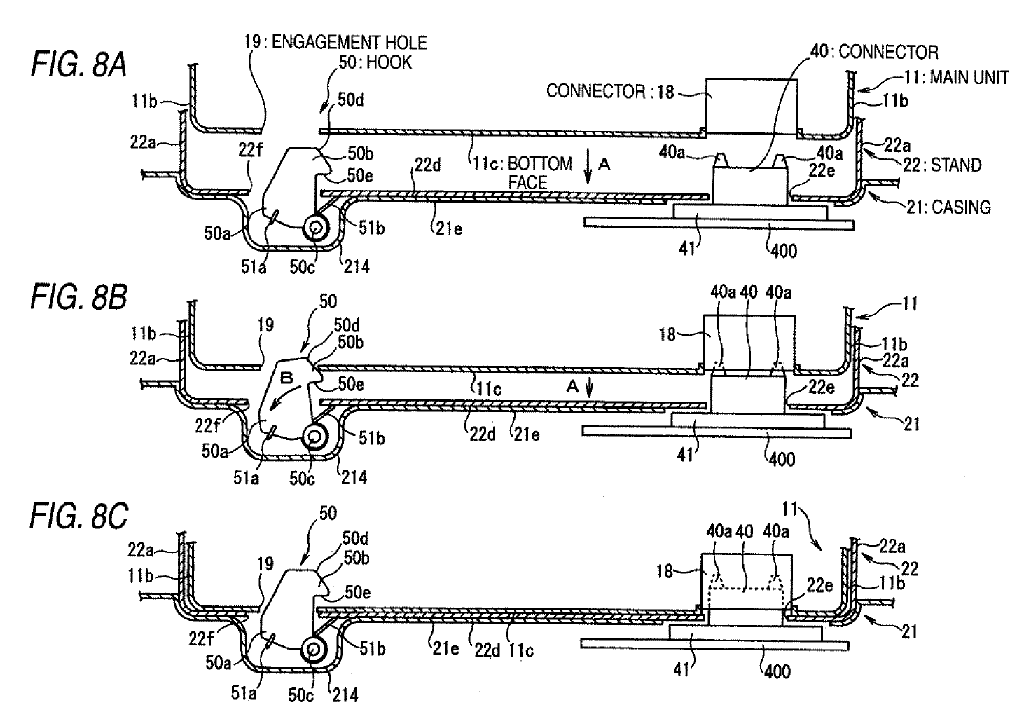

FIGS. 8A to 8C show the attaching operation of the computer 10 on the cradle 20. The computer 10 is pushed down to the arrow A direction along the back wall 22d of the stand 22. Before the computer is attached, the hook 50 is urged by the coil spring 51 and is in an upright state as shown in FIG. 8A. When the computer 10 is pushed down to the arrow A direction, the rim of the engagement hole 19 abuts the inclined face 50d of the hook 50 and causes the hook 50 to generate a reaction force to rotate to the arrow direction B in the figure. According to this reaction force, the hook 50 rotates to the arrow direction B in the figure against the spring force of the coil spring 51 and if the computer 10 is further pushed down, the connector 40 is fitted into the connector 18 on the computer 10 and the hook 50 is restored to the former state by the spring force of the coil spring 51 and engages with the engagement hole 19.

(Detaching Operation)

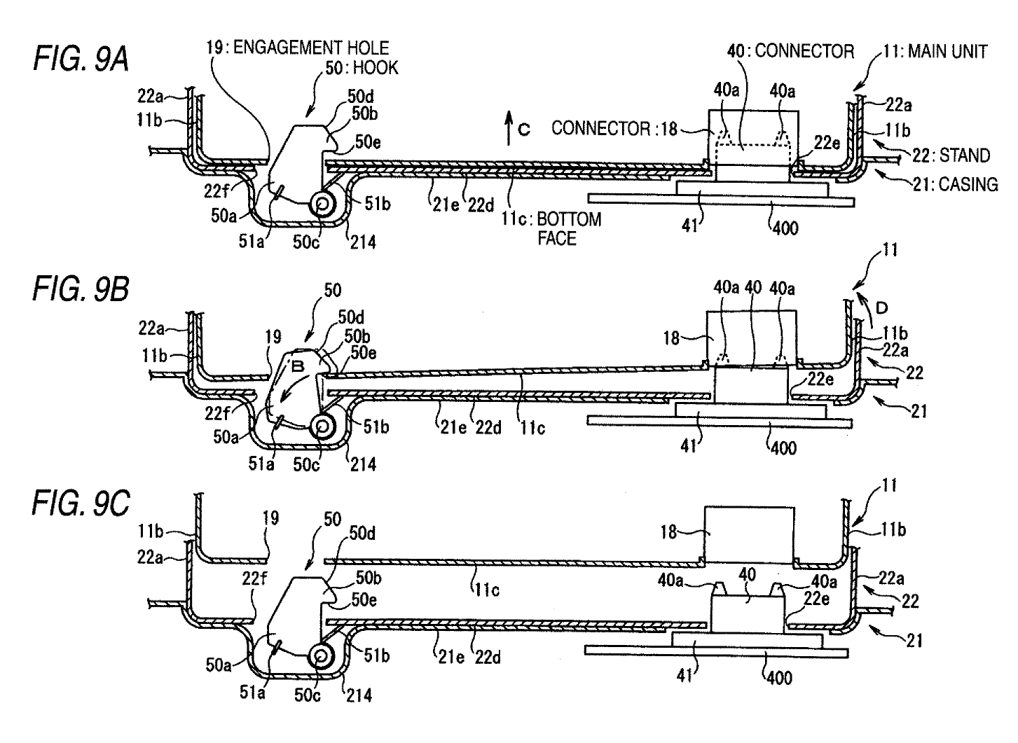

FIGS. 9A to 9C show the detaching operation of the computer 10 from the cradle 20. To remove the computer 10 from the cradle 20, if the computer 10 is lifted up horizontally or the hook 50 side is lifted up, the rim of the engagement hole 19 abuts the horizontal face 50e of the claw part 50b of the hook 50 and the hook 50 cannot be rotated and thus it becomes difficult to remove the computer 10. Then, if the connector 18 side is lifted up to the D direction as shown in FIG. 9B while the computer 10 is lifted up to the upward direction C as shown in FIG. 9A, the hook 50 rotates to the arrow direction B in the figure and is detached from the engagement hole 19 and the computer 10 can be removed from the cradle 20.

### Advantages of the First Embodiment of the Invention

According to the first embodiment, since the hook 50 is provided on the opposite to the connector 40, a posture of the computer 10 in removing from the cradle 20 is limited and a load on the connectors 18 and 40 can be lightened.

### Second Embodiment

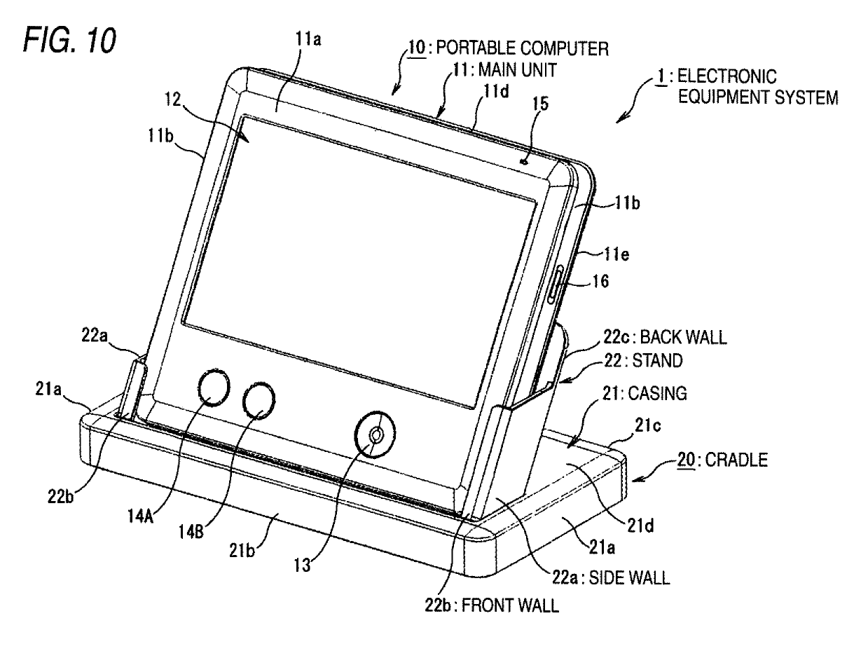

FIG. 10 is an exemplary perspective view of an electronic equipment system according to a second embodiment of the invention. In the first embodiment, the left and right side walls 22a of the stand 22 have the same length; in the second embodiment, a side wall 22a on the side of a connector 40 is made higher than an opposite side wall 22a.

According to the second embodiment, when a computer 10 is removed from a cradle 20, the right side wall 22a limits inclination of the computer 10 to the right. Consequently it becomes easy to detach a hook 50 and to remove the computer 10.

It is to be understood that the invention is not limited to the above-described specific embodiment thereof and various modifications may be made without departing from the spirit and the scope of the invention.

What is claimed is:

1. A support device comprising:
a casing having one end, the other end opposite to the one end, and a placement plane for mounting an electronic equipment having a certain width;
an external connection terminal for connecting to the electronic equipment, the external connection terminal being provided on the placement plane at a position at a first distance from a center of the placement plane to the one end; and
an engagement piece having a claw part and being provided on the placement plane at a position at a second distance from the center of the placement plane to the other end.

2. The support device according to claim 1, wherein the claw part is elastically supported, so that the claw part is rotatable from a first state to a second state by applying a certain force, the first state in which the claw part projects from the placement plane with the claw part aimed at the one end, the second state in which the claw part projects to a perpendicular direction from the placement plane with at least a part of the claw part projecting from the placement plane.

3. The support device according to claim 1, wherein the casing has a back wall and a pair of side walls, the back wall extended from the one end to the other end and having a width between both end parts thereof larger than the certain width of the electronic equipment, the pair of side walls provided at both end parts of the back wall.

4. The support device according to claim 3, wherein a height of the side wall at the one end from the placement plane is larger than a height of the side wall at the other end from the placement plane.

5. An electronic equipment system comprising:
an electronic equipment comprising a first casing having a first face, a first external connection terminal provided at a position at a first distance from a center of the first face to a certain direction on the first face, and an engagement hole provided at a position at a second distance from the center of the first face to an opposite direction against the certain direction on the first face; and
a support device comprising a second casing having one end, the other end opposite to the one end, and a placement plane for mounting the electronic equipment having a certain width, a second external connection terminal for connecting to the electronic equipment, the second external connection terminal being provided on the placement plane of the second casing and placed at a position at a first distance from a center of the placement plane to the one end on the placement plane, and an engagement piece having a claw part and being provided on the placement plane of the second casing at a position at a second distance from the center of the placement plane to the other end.

6. An electronic equipment comprising:
a casing having a first face;
an external connection terminal provided at a position at a first distance from a center of the first face to a certain direction on the first face; and
an engagement hole provided at a position at a second distance from the center of the first face to an opposite direction against the certain direction on the first face.
